(19) United States
(12) Patent Application Publication
(10) Pub. No.: US 2019/0319218 A1
(43) Pub. Date: Oct. 17, 2019

(54) DISPLAY DEVICE AND METHOD OF MANUFACTURING THE SAME

(71) Applicant: Sharp Kabushiki Kaisha, Sakai City, Osaka (JP)

(72) Inventors: Jumpei TAKAHASHI, Sakai City (JP); Tohru SONODA, Sakai City (JP); Yoshinobu MIYAMOTO, Sakai City (JP)

(21) Appl. No.: 16/473,274

(22) PCT Filed: Sep. 28, 2017
(86) PCT No.: PCT/JP2017/035181

§ 371 Date: Jun. 25, 2019

(51) Int. Cl. H01L 51/52; H01L 51/56

(52) U.S. Cl. CPC H01L 51/5253; H01L 27/3244; H01L 51/56

(57) ABSTRACT

In a sealing film in which a first inorganic film, an organic film, and a second inorganic film are layered in that order, a high-wettability region having a relatively high wettability with respect to droplets configured to become the organic film, and a low-wettability region having a relatively low wettability with respect to the droplets, are arranged in an alternating manner on an organic film side surface of the first inorganic film.

### TECHNICAL FIELD

The disclosure relates to a display device and a method of manufacturing the same.

### BACKGROUND ART

In recent years, organic EL display devices, which use organic electroluminescence (EL) elements and are of the self-luminous type, have attracted attention as display devices that can replace liquid crystal display devices. For the organic EL display device, a seal structure is proposed to inhibit the degradation of the organic EL element due to the penetration of, for example, moisture and oxygen. The seal structure includes a sealing film covering the organic EL element, and the sealing film includes a stack of an inorganic film and an organic film.

For example, PTL 1 discloses a display device including a thin film sealing layer. The thin film sealing layer has a layered structure in which an inorganic film layer formed through CVD (chemical vapor deposition) or the like, and an organic film layer formed through an ink-jet method or the like, are arranged in an alternating manner, and the thin film sealing layer covers an organic light emitting element.

### CITATION LIST

### Patent Literature

PTL 1: JP 2014-86415 A

### SUMMARY

### Technical Problem

When an organic film constituting a sealing film is formed through an ink-jet method, as with the display device disclosed in the aforementioned PTL 1, droplets that will become the organic film may spread to the periphery in a non-uniform manner due to the wettability of the surface onto which the droplets are ejected with respect to the organic film. When such non-uniformity occurs, there is a risk that after the droplets harden, flaws will be present in the organic film in areas where the droplets were insufficient.

Having been conceived in light of the foregoing point, an object of the disclosure is to suppress the occurrence of flaws in an organic film, which arise due to insufficient droplets of an organic material that will become the organic film, in a sealing film formed by layering a first inorganic film, the organic film, and a second inorganic film.

### Solution to Problem

To achieve the above-described object, a display device according to the disclosure includes: a base substrate in which a display region in which an image is displayed and a frame region located in the periphery of the display region are defined; a light emitting element provided in the display region of the base substrate; and a sealing film in which a first inorganic film, an organic film, and a second inorganic film are layered in that order, the sealing film being provided in the display region and the frame region, the sealing film covering the light emitting element, wherein a high-wettability region having a relatively high wettability with respect to droplets configured to become the organic film, and a low-wettability region having a relatively low wettability with respect to the droplets, are arranged in an alternating manner on an organic film side surface of the first inorganic film.

### Advantageous Effects of Disclosure

According to the disclosure, the high-wettability region having a relatively high wettability with respect to the droplets that will become the organic film, and the low-wettability region having a relatively low wettability with respect to the droplets, are arranged in an alternating manner on the organic film side surface of the first inorganic film. Accordingly, in a sealing film in which the first inorganic film, the organic film, and the second inorganic film are layered, a situation in which flaws occur in the organic film due to the droplets of an organic material that will become the organic layer being insufficient can be suppressed.

### BRIEF DESCRIPTION OF DRAWINGS

FIG. 1 is a plan view of an organic EL display device according to a first embodiment of the disclosure, schematically illustrating the configuration of the device.

FIG. 2 is a cross-sectional view of the organic EL display device taken along line II-II in FIG. 1, schematically illustrating the configuration of the device.

FIG. 3 is a cross-sectional view illustrating, in detail, the configuration of a display region of the organic EL display device according to the first embodiment of the disclosure.

FIG. 4 is a cross-sectional view of an organic EL layer included in the organic EL display device according to the first embodiment of the disclosure.

FIG. 5 is a perspective view of a first inorganic film in a sealing film included in the organic EL display device according to the first embodiment of the disclosure.

FIG. 6 is a perspective view illustrating a method of forming the first inorganic film in the sealing film included in the organic EL display device according to the first embodiment of the disclosure.

FIG. 7 is a plan view illustrating the spreading of droplets ejected onto the first inorganic film in the sealing film included in the organic EL display device according to the first embodiment of the disclosure.

FIG. 8 is a perspective view illustrating a variation on the first inorganic film in the sealing film included in the organic EL display device according to the first embodiment of the disclosure.

FIG. 9 is a cross-sectional view illustrating a frame region of an organic EL display device according to a second embodiment of the disclosure.

FIG. 10 is a schematic view illustrating the cross-sectional shape of a circumferential end part of an organic film in a sealing film included in the organic EL display device according to the second embodiment of the disclosure.

FIG. 11 is a plan view illustrating a method of forming a first inorganic film in the sealing film included in the organic EL display device according to the second embodiment of the disclosure.

FIG. 12 is a plan view illustrating a variation on the method of forming the first inorganic film in the sealing film included in the organic EL display device according to the second embodiment of the disclosure.

FIG. 13 is a plan view illustrating a variation on the first inorganic film in the sealing film included in the organic EL display device according to the second embodiment of the disclosure.

FIG. 14 is a plan view illustrating another variation on the first inorganic film in the sealing film included in the organic EL display device according to the second embodiment of the disclosure.

### DESCRIPTION OF EMBODIMENTS

Embodiments of the disclosure will be described in detail below with reference to the drawings. The disclosure is not limited to the embodiments described below.

### First Embodiment

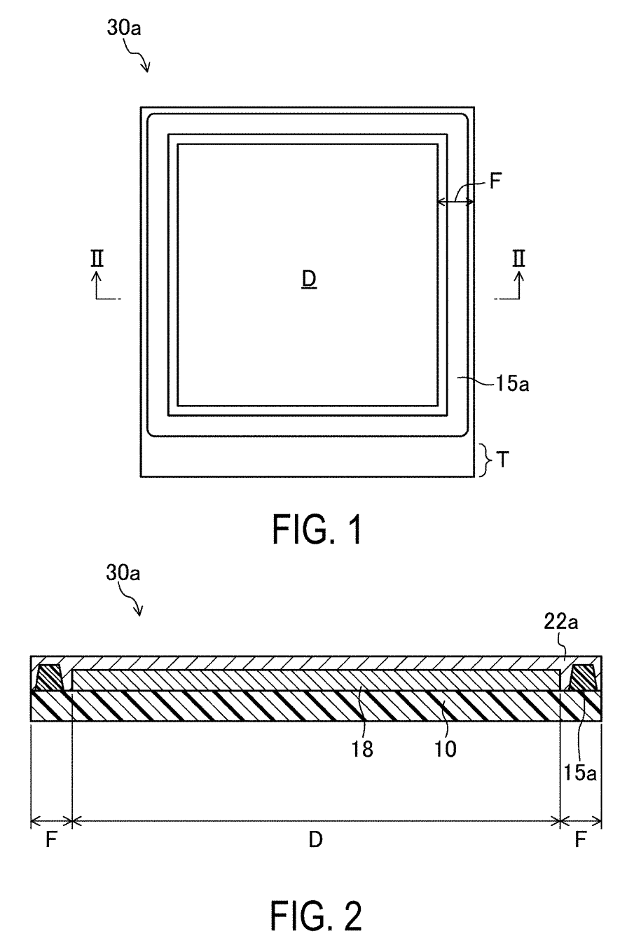

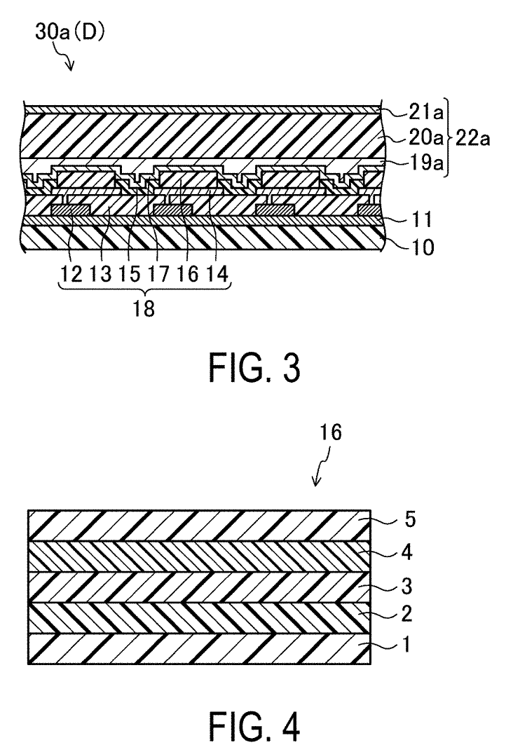

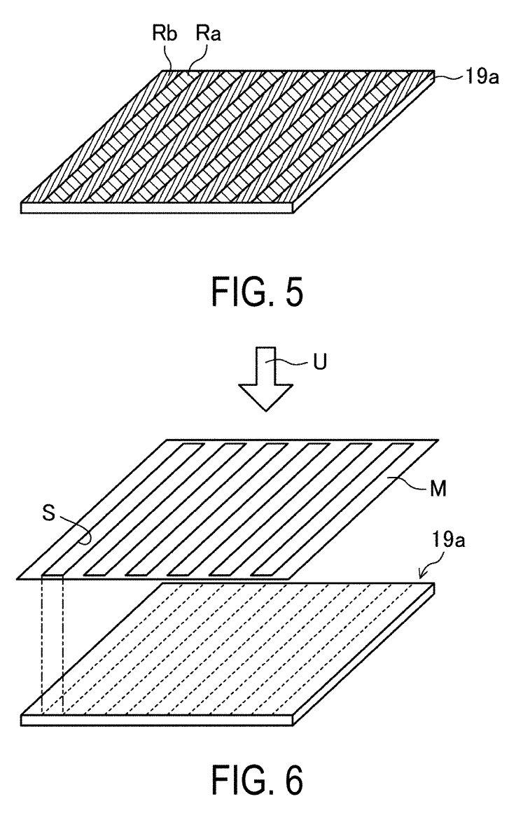

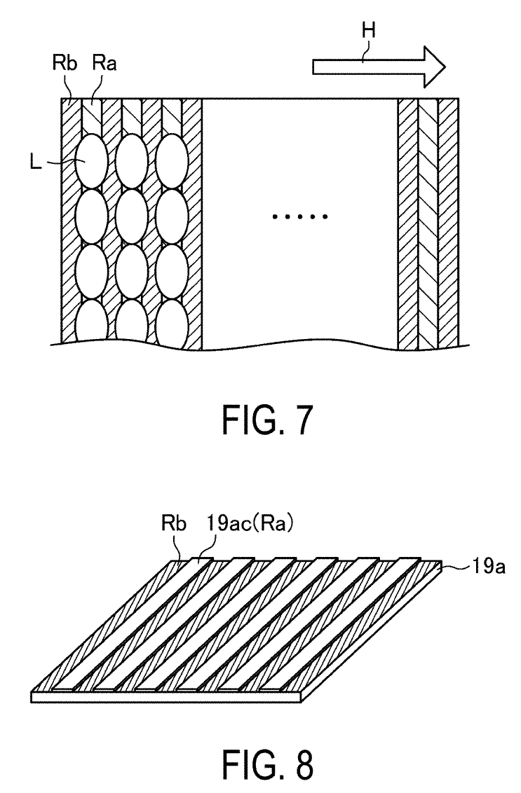

FIGS. 1 to 8 illustrate the first embodiment of a display device and a method of manufacturing the same according to the disclosure. In the following embodiments, an organic EL display device including an organic EL element will be described as an example of a display device including a light emitting element. Here, FIG. 1 is a plan view of an organic EL display device 30a according to the present embodiment, schematically illustrating the configuration of the device. FIG. 2 is a cross-sectional view of the organic EL display device 30a taken along line II-II in FIG. 1, schematically illustrating the configuration of the device. FIG. 3 is a cross-sectional view illustrating, in detail, the configuration of a display region D in the organic EL display device 30a. FIG. 4 is a cross-sectional view of an organic EL layer 16 included in the organic EL display device 30a. FIG. 5 is a perspective view of a first inorganic film 19a in a sealing film 22a included in the organic EL display device 30a. FIG. 6 is a perspective view illustrating a method of forming the first inorganic film 19a in the sealing film 22a included in the organic EL display device 30a. FIG. 7 is a plan view illustrating the spreading of droplets L ejected onto the first inorganic film 19a in the sealing film 22a included in the organic EL display device 30a. FIG. 8 is a perspective view illustrating a variation on the first inorganic film 19a in the sealing film 22a included in the organic EL display device 30a.

As illustrated in FIGS. 1 to 3, the organic EL display device 30a includes a base substrate 10, an organic EL element 18, and the sealing film 22a. The organic EL element 18 is provided, as a light emitting element, upon the base substrate 10 with a base coating film 11 interposed therebetween, and the sealing film 22a is provided covering the organic EL element 18. Here, in the organic EL display device 30a, a display region D in which images are displayed is defined as a rectangular shape as illustrated in FIG. 1, and in the display region D, a plurality of pixels are arranged in a matrix. Each of the pixels includes a subpixel for displaying a red tone, a subpixel for displaying a green tone, and a subpixel for displaying a blue tone, for example. These subpixels are disposed adjacent to one another. As illustrated in FIG. 1, in the organic EL display device 30a, a frame-shaped frame region F is defined in the periphery of the display region D. A terminal portion T at an end part of the frame region F corresponding to the bottom of the drawing.

The base substrate 10 is a plastic substrate formed from a polyimide resin, for example, a glass substrate, or the like.

The base coating film 11 is an inorganic insulating film such as a silicon oxide film or a silicon nitride film, for example.

As illustrated in FIG. 2, the organic EL element 18 is provided in the display region D. As illustrated in FIG. 3, the organic EL element 18 includes a plurality of TFTs 12, a flattening film 13, a plurality of first electrodes 14, a partition 15, a plurality of organic EL layers 16, and a second electrode 17, provided in that order on the base coat layer 11.

The TFT 12 is a switching element provided for each of the subpixels in the display region D. Here, the TFTs 12 each include, for example, semiconductor layer, a gate insulating film, a gate electrode, an interlayer insulating film, and source and drain electrodes. The semiconductor layer is provided on the base coating film 11 in an island shape. The gate insulating film is provided covering the semiconductor layer. The gate electrode is provided on the gate insulating film so as to overlap with a part of the semiconductor layer. The interlayer insulating film is provided covering the gate electrode. The source and drain electrodes are arranged separated from each other. In the present embodiment, the top-gate type is described as an example of the TFT 12, but the TFT 12 may be of the bottom-gate type.

As illustrated in FIG. 3, the flattening film 13 is disposed to cover the TFTs 12 except for a portion of each of the drain electrodes, and is provided so as to flatten the surface shape formed by the TFTs 12. Here, the flattening film 13 is composed of a colorless transparent organic resin material such as an acrylic resin, for example.

As illustrated in FIG. 3, the plurality of first electrodes 14 are provided in a matrix over the flattening film 13, corresponding to the plurality of subpixels. Here, as illustrated in FIG. 3, the first electrodes 14 are connected to the respective drain electrodes of the TFTs 12 via respective contact holes formed in the flattening film 13. The first electrode 14 functions to inject holes into the organic EL layer 16. It is more preferable that the first electrodes 14 include a material having a large work function to improve the efficiency of hole injection into the organic EL layer 16. Examples of materials that may be included in the first electrode 14 include metal materials, such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Further examples of materials that may be included in the first electrode 14 include alloys, the examples of which include magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). Further examples of materials that may be included in the first electrode 14 include electrically conductive oxides, the examples of which include tin oxide (SnO), zinc oxide (ZnO), indium tin oxide (ITO), and indium zinc oxide (IZO). The first electrode 14 may include a stack of two or more layers of any of the above-mentioned materials. Examples of materials having a large work function include indium tin oxide (ITO) and indium zinc oxide (IZO).

As illustrated in FIG. 3, the partition 15 is disposed in a lattice pattern so as to cover the peripheral portions of each of the first electrodes 14. Examples of materials that may constitute the partition 15 include inorganic films such as silicon oxide (SiO₂), silicon nitride (SiNx (x is a positive number)) such as trisilicon tetranitride (Si₃N₄), and silicon oxynitride (SiNO), or organic films such as polyimide resins, acrylic resins, polysiloxane resins, and novolak resins. As illustrated in FIG. 1, a damming wall 15a, which is formed in the same layer and from the same material as the partition 15, is provided in the frame region F of the organic EL display device 30a in a frame shape so as to surround the organic EL element 18.

As illustrated in FIG. 3, the plurality of organic EL layers 16 are arranged in a matrix on the respective first electrodes 14, and correspond to the respective subpixels. Here, as illustrated in FIG. 4, the organic EL layers 16 each include a hole injection layer 1, a hole transport layer 2, a light-emitting layer 3, an electron transport layer 4, and an electron injection layer 5, which are arranged in that order over the first electrode 14.

The hole injection layer 1 is also referred to as an anode buffer layer, and functions to reduce the energy level difference between the first electrode 14 and the organic EL layer 16 so as to improve the efficiency of hole injection into the organic EL layer 16 from the first electrode 14. Examples of materials that may constitute the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 functions to improve the efficiency of hole transport from the first electrode 14 to the organic EL layer 16. Examples of materials that may constitute the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where, when a voltage is applied via the first electrode 14 and the second electrode 17, holes and electrons are injected from the first electrode 14 and the second electrode 17, respectively, and the holes and the electrons recombine. Here, the light-emitting layer 3 is formed from a material having a high light emitting efficiency. Examples of materials that may constitute the light-emitting layer 3 include metal oxinoid compounds (8-hydroxyquinoline metal complexes), naphthalene derivatives, anthracene derivatives, diphenyl ethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 functions to facilitate the efficient migration of the electrons to the light-emitting layer 3. Examples of materials that may constitute the electron transport layer 4 include organic compounds, the examples of which include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 functions to reduce the energy level difference between the second electrode 17 and the organic EL layer 16, to improve the efficiency of electron injection into the organic EL layer 16 from the second electrode 17. Because of this function, the driving voltage for the organic EL element 18 can be reduced. The electron injection layer 5 is also referred to as a cathode buffer layer. Examples of materials that may constitute the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂); aluminum oxide (Al₂O₃); and strontium oxide (SrO).

As illustrated in FIG. 3, the second electrode 17 is provided so as to cover the organic EL layers 16 and the partitions 15, and is provided in common for the plurality of subpixels. The second electrode 17 functions to inject electrons into the organic EL layer 16. It is more preferable that the second electrode 17 includes a material having a small work function to improve the efficiency of electron injection into the organic EL layer 16. Examples of materials that may constitute the second electrode 17 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). Further examples of materials that may be included in the second electrode 17 include alloys, the examples of which include magnesium (Mg)-copper (Cu), magnesium (Mg)-silver (Ag), sodium (Na)-potassium (K), astatine (At)-astatine oxide (AtO₂), lithium (Li)-aluminum (Al), lithium (Li)-calcium (Ca)-aluminum (Al), and lithium fluoride (LiF)-calcium (Ca)-aluminum (Al). Further examples of materials that may be included in the second electrode 17 include electrically conductive oxides, the examples of which include tin oxide (SnO), zinc oxide (ZnO), indium tin oxide (ITO), and indium zinc oxide (IZO). The second electrode 17 may include a stack of two or more layers of any of the above-mentioned materials. Examples of materials having a small work function include magnesium (Mg), lithium (Li), lithium fluoride (LiF), magnesium (Mg)-copper (Cu), magnesium (Mg)-silver (Ag), sodium (Na)-potassium (K), lithium (Li)-aluminum (Al), lithium (Li)-calcium (Ca)-aluminum (Al), and lithium fluoride (LiF)-calcium (Ca)-aluminum (Al).

As illustrated in FIG. 3, the sealing film 22a includes the first inorganic film 19a, an organic film 20a, and a second inorganic film 21a. The first inorganic film 19a is provided so as to cover the organic EL element 18. The organic film 20a is provided on the first inorganic film 19a. The second inorganic film 21a is provided so as to cover the organic film 20a.

The first inorganic film 19a is composed of an inorganic insulating film such as a silicon nitride film, for example. As illustrated in FIG. 5, high-wettability regions Ra having a relatively high wettability (e.g., a contact angle of less than 5° with respect to the droplets L that will become the organic film 20a, and low-wettability regions Rb having a relatively low wettability (e.g., a contact angle of 5° or more) with respect to the droplets L, are arranged on the organic film 20a side surface of the first inorganic film 19a. The high-wettability regions Ra and the low-wettability regions Rb are arranged in an alternating manner in an application direction of the organic resin material that will become the organic film 20a (described later). Here, the pitch of the high-wettability regions Ra is approximately from 11 μm to 16 μm, for example. The width of the high-wettability regions Ra is approximately ½ the pitch of the high-wettability regions Ra. The high-wettability regions Ra and the low-wettability regions Rb are provided so as to be orthogonal to the application direction of the organic resin material that will become the organic film 20a. The contact angle, which serves as an index expressing wettability, is measured according to the sessile drop technique described in JIS R3257:1999. However, when measuring the contact angle in the present embodiment, a CVD vapor deposition substrate is used instead of a glass substrate, and an ink material is used instead of water.

The organic film 20a is composed of an organic resin material such as an acrylate, epoxy, silicone, polyurea, parylene, polyimide, polyamide, or the like, for example.

The second inorganic film 21a is composed of an inorganic insulating film such as a silicon nitride film, a silicon oxide film, a silicon oxynitride film, or the like, for example.

The organic EL display device 30a configured as described above is flexible. In each of the subpixels, the light-emitting layer 3 of the organic EL layer 16 is caused, via the TFT 12, to emit light as appropriate so as to display images.

A method of manufacturing the organic EL display device 30a according to the present embodiment will be described next. Note that the method of manufacturing the organic EL display device 30a according to the present embodiment includes forming an organic EL element and forming a sealing film.

### Forming Organic EL Element

Using a known method, the base coating film 11, the organic EL element 18 (the TFTs 12, the flattening film 13, the first electrodes 14, the partitions 15, the organic EL layers 16 (the hole injection layer 1, the hole transport layer 2, the light-emitting layer 3, the electron transport layer 4, and the electron injection layer 5), the second electrode 17), and the damming wall 15a are formed on the surface of the base substrate 10, which is made from a polyimide resin, for example.

### Forming Sealing Film

First, for example, an inorganic insulating film such as a silicon nitride film is formed through plasma CVD at a thickness of approximately several tens of nm to several μm, so as to cover the organic EL element 18 formed in the above-described formation of the organic EL element. Then, as illustrated in FIG. 6, the first inorganic film 19a is formed by irradiating the surface of the inorganic insulating film with ultraviolet light U over a mask M (forming a first inorganic film). Here, a plurality of slits S are formed in the mask M extending parallel to each other.

Next, the organic film 20a is formed by using an ink-jet method to eject an organic resin material such as an acrylate, at a thickness of approximately several μm to several tens of μm, onto the entire surface of the substrate on which the first inorganic film 19a has been formed (a process of forming an organic film). Here, if the droplets L of the organic resin material are ejected onto the substrate surface on which the first inorganic film 19a is formed using an ink-jet method, the droplets L spread easily along the high-wettability regions Ra in the vertical direction of the drawing in FIG. 7. Accordingly, the organic film 20a can be formed so that it is difficult for flaws to arise due to the droplets L of the organic resin material being insufficient. Note that the pitch of the droplets L in an application direction H is approximately from 11 μm to 16 μm, for example, and the pitch of the droplets L in a direction orthogonal to the application direction H (the pitch of the nozzles of the ink-jet device) is approximately 70 μm, for example.

Furthermore, the second inorganic film 21a is formed by depositing an inorganic insulating film, such as a silicon nitride film, through plasma CVD at a thickness of approximately several tens of nm to several μm, onto the substrate on which the organic film 20a has been formed. As a result, the sealing film 22a composed of the first inorganic film 19a, the organic film 20a, and the second inorganic film 21a is formed (a process of forming a second inorganic film).

The present embodiment describes a method of forming the high-wettability regions Ra by irradiating the surface of an inorganic insulating film such as a silicon nitride film with ultraviolet light U as an example. However, as illustrated in FIG. 8, the high-wettability regions Ra may be formed by forming another inorganic film 19ac, such as a silicon oxide film, in stripes on the surface of the first inorganic film 19a, which is formed from a silicon nitride film or the like.

The organic EL display device 30a of the present embodiment can be manufactured in this manner.

As described thus far, according to the organic EL display device 30a and the method of manufacturing the same of the present embodiment, in the sealing film 22a, the high-wettability regions Ra having a relatively high wettability with respect to the droplets L of the organic resin material that will become the organic film 20a, and the low-wettability regions Rb having a relatively low wettability with respect to the droplets L, are arranged on the organic film 20a side surface of the first inorganic film 19a, with the high-wettability regions Ra and the low-wettability regions Rb being arranged in an alternating manner. Here, when the droplets L are applied using a typical ink-jet method, the pitch of the droplets L in the direction orthogonal to the application direction H is wider than the pitch of the droplets L in the application direction H. Accordingly, arranging the high-wettability regions Ra and the low-wettability regions Rb in an alternating manner along the application direction H in which the droplets L are applied through the ink-jet method makes it easier for droplets L separated in the direction orthogonal to the application direction H to merge with each other. As such, an organic film 20a that suppresses the occurrence of flaws caused by the droplets L being insufficient can be formed. This in turn makes it possible to suppress the occurrence of flaws in the organic film 20a caused by the droplets L of the organic material that will become the organic film 20a being insufficient, in the sealing film 22a formed by layering the first inorganic film 19a, the organic film 20a, and the second inorganic film 21a.

Additionally, according to the organic EL display device 30a and the method of manufacturing the same of the present embodiment, the high-wettability regions Ra are formed by irradiation with ultraviolet light U. This makes it possible to manufacture the organic EL display device 30a including the organic film 20a, in which the occurrence of flaws caused by insufficient droplets L is suppressed, while suppressing manufacturing costs.

### Second Embodiment

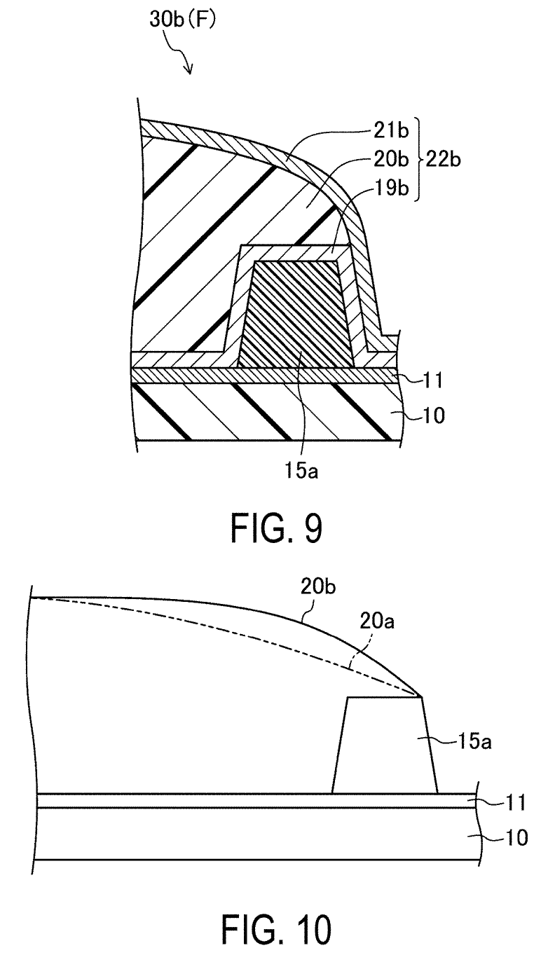

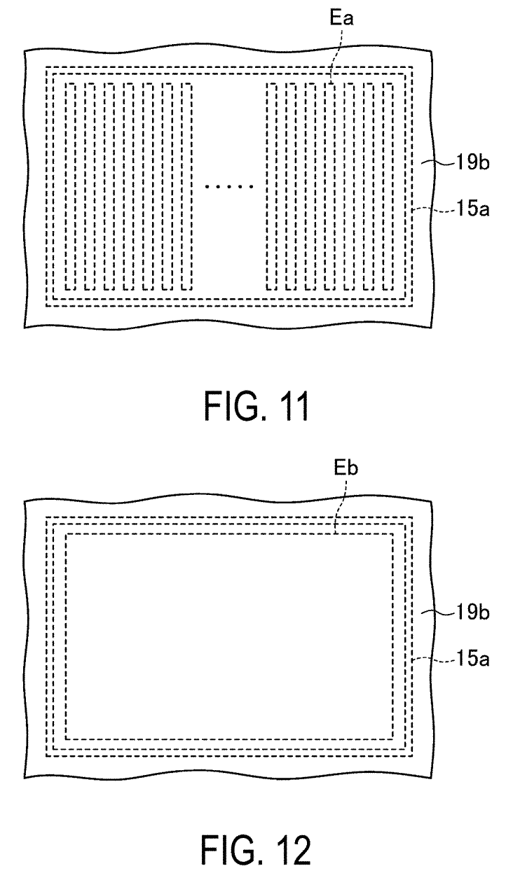

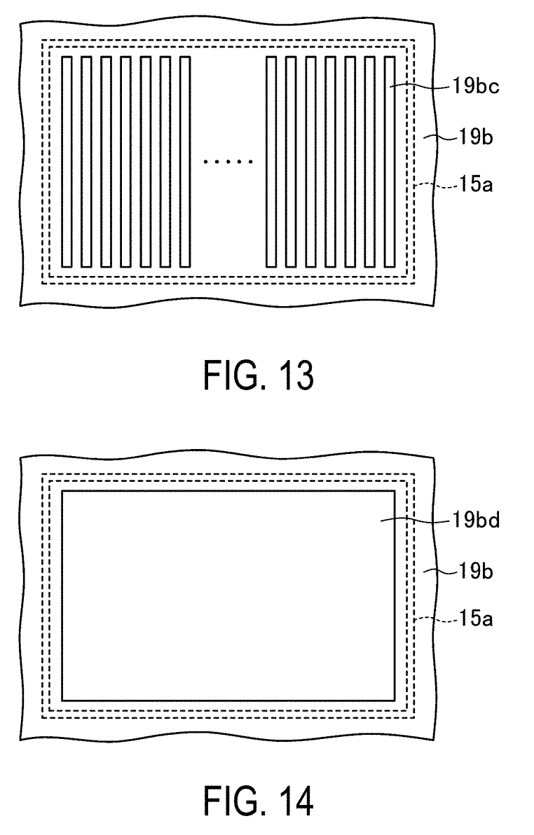

FIGS. 9 to 12 illustrate the second embodiment of a display device and a method of manufacturing the same according to the disclosure. Here, FIG. 9 is a cross-sectional view illustrating a frame region in an organic EL display device 30b according to the present embodiment. FIG. 10 is a schematic view illustrating the cross-sectional shape of a circumferential end part of an organic film 20b in a sealing film 22b included in the organic EL display device 30b. FIG. 11 is a plan view illustrating a method of forming a first inorganic film 19b in the sealing film 22b included in the organic EL display device 30b. FIG. 12 is a plan view illustrating a variation on the method of forming the first inorganic film 19b in the sealing film 22b included in the organic EL display device 30b. FIGS. 13 and 14 are plan views illustrating first and second variations on the first inorganic film 19b in the sealing film 22b included in the organic EL display device 30b.

The foregoing first embodiment describes the organic EL display device 30a, in which the wettability of the first inorganic film 19a with respect to the droplets L is controlled in the display region D, as an example. The present embodiment, however, will describe the organic EL display device 30b, in which the wettability of the first inorganic film 19b with respect to the droplets L is controlled in the display region D and the frame region F, as an example.

As illustrated in FIG. 9, the organic EL display device 30b includes the base substrate 10, the organic EL element 18 (see FIGS. 2 and 3), and the sealing film 22b. The organic EL element 18 is provided as a light emitting element upon the base substrate 10 with the base coating film 11 interposed therebetween, and the sealing film 22b is provided covering the organic EL element 18.

As illustrated in FIG. 9, the sealing film 22b includes the first inorganic film 19b, the organic film 20b, and a second inorganic film 21b. The first inorganic film 19b is provided so as to cover the organic EL element 18. The organic film 20b is provided on the first inorganic film 19b. The second inorganic film 21b is provided so as to cover the organic film 20b.

The first inorganic film 19b is composed of an inorganic insulating film such as a silicon nitride film, for example. As illustrated in FIG. 11, an irradiated region Ea that has been irradiated with the ultraviolet light U is provided in stripes on the organic film 20b side surface of the first inorganic film 19b in the display region D. Thus, like the first inorganic film 19a of the above-described first embodiment, the high-wettability regions Ra having a relatively high wettability with respect to the droplets L that will become the organic film 20b, and the low-wettability regions Rb having a relatively low wettability with respect to the droplets L, are arranged in an alternating manner. However, of the organic film 20b side surface of the first inorganic film 19b, regions overlapping with the damming wall 15a, and regions on the outer sides of the stated overlapping regions, are not irradiated with the ultraviolet light U. That surface therefore has a relatively low wettability with respect to the droplets L. The present embodiment describes a configuration in which the high-wettability regions Ra and the low-wettability regions Rb are arranged in an alternating manner in the display region D as an example. However, as illustrated in FIG. 12, an irradiated region Eb that is irradiated by ultraviolet rays U may be provided on the inner sides of the damming wall 15a (in the entire display region D), so that only the surface of the first inorganic film 19b above the damming wall 15a is a region having a low wettability.

The organic film 20b is composed of an organic resin material such as an acrylate, epoxy, silicone, polyurea, parylene, polyimide, polyamide, or the like, for example. As described above, the surface of the first inorganic film 19b overlapping with the damming wall 15a is not irradiated with the ultraviolet light U, and thus has a lower wettability than the high-wettability regions Ra within the display region D, in the same manner as the low-wettability regions Rb within the display region D. Therefore, as illustrated in FIG. 10, an incline of the circumferential end parts of the organic film 20b is steeper than an incline of the circumferential end parts of the organic film 20a according to the above-described first embodiment (see the double-dot-dash line). Accordingly, a situation in which the circumferential end parts of the organic film 20b broaden in the frame region F can be suppressed, which makes it possible to narrow the width of the frame region F.

The second inorganic film 21b is composed of an inorganic insulating film such as a silicon nitride film, a silicon oxide film, a silicon oxynitride film, or the like, for example.

The above-described organic EL display device 30b is flexible. In each of the subpixels, the light-emitting layer 3 of the organic EL layer 16 is caused, via the TFT 12, to emit light as appropriate so as to display images.

The present embodiment describes a method of irradiating the surface of the first inorganic film 19b with the ultraviolet light U to give that surface a relatively low wettability as an example. However, as illustrated in FIG. 13, another inorganic film 19bc, such as a silicon oxide film, may be formed in stripes on the surface of the first inorganic film 19b in the display region D, and the high-wettability regions Ra and the low-wettability regions Rb may be arranged in an alternating manner in the display region D. Furthermore, as illustrated in FIG. 14, another inorganic film 19bd, such as a silicon oxide film, may be formed on the inner sides of the damming wall 15a (in the entire display region D), so that only the surface of the first inorganic film 19b above the damming wall 15a is a region having a low wettability.

The organic EL display device 30b can be manufactured by, for example, changing the region irradiated with the ultraviolet light U in the method of manufacturing the organic EL display device 30a described above in the first embodiment.

As described thus far, according to the organic EL display device 30b and the method of manufacturing the same of the present embodiment, in the sealing film 22b, the high-wettability regions Ra having a relatively high wettability with respect to the droplets L of the organic resin material that will become the organic film 20b, and the low-wettability regions Rb having a relatively low wettability with respect to the droplets L, are arranged on the organic film 20b side surface of the first inorganic film 19b, with the high-wettability regions Ra and the low-wettability regions Rb being arranged in an alternating manner. Here, when the droplets L are applied using a typical ink-jet method, the pitch of the droplets L in the direction orthogonal to the application direction H is wider than the pitch of the droplets L in the application direction H. Accordingly, arranging the high-wettability regions Ra and the low-wettability regions Rb in an alternating manner along the direction H in which the droplets L are applied through the ink-jet method makes it easier for droplets L separated in the direction orthogonal to the application direction H to merge with each other. As a result, an organic film 20b that suppresses the occurrence of flaws caused by the droplets L being insufficient can be formed. This in turn makes it possible to suppress the occurrence of flaws in the organic film 20b caused by the droplets L being insufficient, of the organic material that will become the organic film 20b, in the sealing film 22b formed by layering the first inorganic film 19b, the organic film 20b, and the second inorganic film 21b.

Additionally, according to the organic EL display device 30b and the method of manufacturing the same of the present embodiment, the high-wettability regions Ra are formed by irradiation with ultraviolet light U. This makes it possible to manufacture the organic EL display device 30b including the organic film 20b, in which the occurrence of flaws caused by insufficient droplets L is suppressed, while suppressing manufacturing costs.

Furthermore, according to the organic EL display device 30b and the method of manufacturing the same of the present embodiment, the surface of the first inorganic film 19b provided above a damming wall 15b has a lower wettability with respect to the droplets L that will become the organic film 20b than the surface of the first inorganic film 19b provided in the high-wettability regions Ra of the display region D. As such, the circumferential end parts of the organic film 20b have a steep incline. Accordingly, a situation in which the circumferential end parts of the organic film 20b broaden in the frame region F can be suppressed, which makes it possible to narrow the width of the frame region F.

### Other Embodiments

The foregoing embodiments describe an organic EL display device as an example of a display device. However, the disclosure can be applied in any display device including a plurality of light emitting elements driven by current, such as a display device including quantum dot light emitting diodes (QLEDs), which are light emitting elements using a quantum dot-containing layer.

In the embodiments described above, the example of the organic EL layer including the five-layer structure including the hole injection layer, the hole transport layer, the light-emitting layer, the electron transport layer, and the electron injection layer is given. It is also possible that, for example, the organic EL layer may include a three-layer structure including a hole injection-cum-transport layer, a light-emitting layer, and an electron transport-cum-injection layer.

In the embodiments described above, the example of the organic EL display devices including the first electrode as an anode and the second electrode as a cathode. However, the disclosure is also applicable to an organic EL display device, in which the layers of the structure of the organic EL layer are in reverse order, with the first electrode being a cathode and the second electrode being an anode.

The foregoing embodiments describe an organic EL display device in which the electrode of the TFT connected to the first electrode is the drain electrode. However, the disclosure can also be applied in an organic EL display device in which the electrode of the TFT connected to the first electrode is referred to as the source electrode.

### INDUSTRIAL APPLICABILITY

As described above, the disclosure is applicable in flexible display devices.

### REFERENCE SIGNS LIST

D Display region
F Frame region
L Droplets
Ra High-wettability region
Rb Low-wettability region
U Ultraviolet light
10 Base substrate
15a Damming wall
18 Organic EL element (light emitting element)
19a, 19b First inorganic film
19ac, 19bc, 19bd Other inorganic film
20a, 20b Organic film
21a, 21b Second inorganic film
22a, 22b Sealing film
30a, 30b Organic EL display device

1. A display device comprising:
a base substrate in which a display region, in which an image is displayed, and a frame region located in the periphery of the display region are defined;
a light emitting element provided in the display region of the base substrate; and
a sealing film in which a first inorganic film, an organic film, and a second inorganic film are layered in that order, the sealing film being provided in the display region and the frame region, the sealing film covering the light emitting element,
wherein a high-wettability region having a relatively high wettability with respect to droplets configured to become the organic film, and a low-wettability region having a relatively low wettability with respect to the droplets, are arranged in an alternating manner on an organic film side surface of the first inorganic film.

2. The display device according to claim 1,
wherein the high-wettability region is formed by irradiation with ultraviolet light.

3. The display device according to claim 1,
wherein another inorganic film that is different from the first inorganic film is provided in the high-wettability region.

4. The display device according to claim 1,
wherein a damming wall that contacts a circumferential end part of the sealing film is provided in the frame region, the damming wall surrounding the light emitting element, and
the high-wettability region and the low-wettability region are arranged in an alternating manner on an inner side of the damming wall.

5. The display device according to claim 4,
wherein a surface of the first inorganic film provided above the damming wall has the same wettability as the low-wettability region with respect to the droplets configured to become the organic film.

6. The display device according to claim 1,
wherein a damming wall that contacts a circumferential end part of the sealing film is provided in the frame region, the damming wall surrounding the light emitting element, and
a surface of the first inorganic film provided above the damming wall has the same wettability as the low-wettability region with respect to the droplets configured to become the organic film.

7. The display device according to claim 6,
wherein a surface of the first inorganic film provided in the display region is irradiated with ultraviolet light.

8. The display device according to claim 6,
wherein another inorganic film that is different from the first inorganic film is provided on a surface of the first inorganic film provided in the display region.

9. (canceled)

10. The display device according to claim 1,
wherein the light emitting element is an organic EL element.

11. A method of manufacturing a display device, the method comprising:
forming a light emitting element on a base substrate; and
forming a sealing film covering the light emitting element,
wherein the forming of the sealing film includes
forming a first inorganic film covering the light emitting element,
forming an organic film by applying an organic film upon the first inorganic film, and
forming a second inorganic film covering the organic film, and
in the forming of the first inorganic film, a high-wettability region having a relatively high wettability with respect to droplets configured to become the organic film, and a low-wettability region having a relatively low wettability with respect to the droplets, are formed on the first inorganic film alternately along a direction in which the organic film is applied in the forming of the organic film.

12. The method of manufacturing a display device according to claim 11,
wherein in the forming of the first inorganic film, the high-wettability region and the low-wettability region are formed orthogonal to the direction in which the organic film is applied in the forming of the organic film.

13. The method of manufacturing a display device according to claim 11,
wherein in the forming of the first inorganic film, the high-wettability region is formed by irradiating a surface of the first inorganic film with ultraviolet light.

14. The method of manufacturing a display device according to claim 13,
wherein a damming wall is provided on the base substrate, the damming wall surrounding the light emitting element, and
in the forming of the first inorganic film, a surface of the first inorganic film above the damming wall is not irradiated with the ultraviolet light.

15. The method of manufacturing a display device according to claim 11,
wherein the light emitting element is an organic EL element.
